(19) United States
(12) Patent Application Publication
(10) Pub. No.: US 2022/0208588 A1
(43) Pub. Date: Jun. 30, 2022

(54) WAFER TRANSFER APPARATUS

(71) Applicant: DISCO CORPORATION, Tokyo (JP)

(72) Inventor: Yoshinori Kakinuma, Tokyo (JP)

(21) Appl. No.: 17/695,417

(22) Filed: Mar. 15, 2022

Related U.S. Application Data
(62) Division of application No. 16/984,728, filed on Aug. 4, 2020.

(30) Foreign Application Priority Data
Aug. 14, 2019 (JP) 2019-148729

(51) Int. Cl. H01L 21/68; B65G 47/244; H01L 23/544; B25J 15/06; H01L 21/683

(52) U.S. Cl. CPC H01L 21/681; B65G 47/244; H01L 2223/54493; B25J 15/0616; H01L 21/6838; H01L 23/544

(57) ABSTRACT

A wafer transfer apparatus includes a holding plate having a holding surface adapted to be opposed to one side of a wafer, a suction holding portion provided so as to be exposed to the holding surface for holding the wafer under suction in a noncontact fashion, three or more restricting members for restricting the movement of the wafer in a direction parallel to the one side of the wafer, each restricting member having a roller portion rotatable about its axis, the roller portion being adapted to come into contacted with the peripheral edge of the wafer held under suction by the suction holding portion, and a moving unit connected to the holding plate for moving the holding plate to thereby transfer the wafer. At least one of the restricting members functions as a rotational drive portion for rotating the roller portion about its axis to thereby rotate the wafer.

This application is a divisional of application Ser. No. 16/984,728, filed Aug. 4, 2020.

### BACKGROUND OF THE INVENTION

### Field of the Invention

The present invention relates to a wafer transfer apparatus for transferring a wafer.

### Description of the Related Art

A plurality of devices is formed on a wafer formed mainly of silicon, gallium arsenide, silicon carbide, or sapphire, for example, thereby producing a device wafer having the plural devices. This device wafer is subjected to processing such as grinding, polishing, and cutting, thereby dividing the device wafer into a plurality of device chips respectively including a device. A plurality of such device wafers to be divided is previously stored in a cassette, and this cassette containing the plural device wafers is transferred to a processing apparatus for processing each device wafer. For example, the processing apparatus is a tape mounter. In the tape mounter, the plural device wafers are taken out of the cassette one by one, and a protective sheet is attached to the front side of each device wafer, in which the protective sheet is formed of resin and has a diameter substantially the same as the diameter of each device wafer. After attaching the protective sheet to each device wafer, each device wafer with the protective sheet is stored again into the cassette, and the cassette thus containing each device wafer with the protective sheet is next transferred to another processing apparatus.

For example, this other processing apparatus is a grinding apparatus. The grinding apparatus usually includes a positioning apparatus for setting each device wafer with the protective sheet at a predetermined position (see JP 1995-211766 A, for example). This positioning apparatus includes a temporary setting table for temporarily setting each device wafer. A disk-shaped mount is provided at the top of the temporary setting table. Further, a plurality of pins is provided along the outer circumference of this mount so as to be movable in the radial direction of the mount.

In the case of setting the device wafer at a substantially central position on the mount, the device wafer is first placed on the mount. Thereafter, the plural pins are moved toward the center of the mount so that the distances from the center of the mount to the plural pins are maintained equal to each other. By making the contact of each pin with the peripheral edge of the device wafer, the device wafer can be set at the substantially central position on the mount. Thereafter, the device wafer is transferred to a substantially central position on a chuck table included in the grinding apparatus, by using a wafer transfer apparatus such as a loading arm. Thereafter, the front side of the device wafer is held through the protective sheet on the chuck table under suction, and the back side of the device wafer is ground by a grinding unit included in the grinding apparatus.

As another example of the positioning apparatus, there is an apparatus for detecting a central position of the device wafer according to an image obtained by a camera (see JP 2011-210827 A, for example). This apparatus includes a temporary setting table for placing the device wafer thereon, imaging means for imaging the peripheral edge of the device wafer placed on the temporary setting table, and a wafer transfer mechanism for transferring the device wafer from the temporary setting table to a chuck table included in the grinding apparatus.

In the case of transferring the device wafer to a substantially central position on the chuck table, the peripheral edge of the device wafer placed on the temporary setting table is first imaged by operating the imaging means to obtain an image, and a central position of the device wafer is next calculated from the image obtained above. The wafer transfer mechanism is rotatable about a predetermined axis so as to describe an arcuate path. After calculating the central position of the device wafer, the temporary setting table is rotated by a predetermined angle so that the central position calculated above lies on the arcuate path of the wafer transfer mechanism. Thereafter, the device wafer is held by a suction pad included in the wafer transfer mechanism, and the wafer transfer mechanism is next rotated to transfer the device wafer to the substantially central position on the chuck table.

### SUMMARY OF THE INVENTION

As described above, prior to transferring the device wafer to the chuck table by using the wafer transfer apparatus, it is necessary to perform positioning (e.g., centering) of the device wafer by using the positioning apparatus including the temporary setting table and the plural pins as provided separately from the wafer transfer apparatus. It is therefore an object of the present invention to provide a wafer transfer apparatus which can perform positioning of the wafer in the condition where the wafer is held by the wafer transfer apparatus.

In accordance with an aspect of the present invention, there is provided a wafer transfer apparatus including a holding table having a holding surface adapted to be opposed to one side of a wafer, a suction holding portion provided so as to be exposed to the holding surface for holding the wafer under suction in a noncontact fashion in the condition where the one side of the wafer is opposed to the holding surface, three or more restricting members for restricting the movement of the wafer with respect to the holding plate in a direction parallel to the one side of the wafer, each restricting member having a roller portion rotatable about its axis, the roller portion being adapted to come into contact with the peripheral edge of the wafer held under suction by the suction holding portion, thereby restricting the movement of the wafer, and a moving unit connected to the holding plate for moving the holding plate to thereby transfer the wafer, in which at least one of the three or more restricting members includes a rotational drive portion for rotating the roller portion about its axis to thereby rotate the wafer in the condition where the roller portion is in contact with the peripheral edge of the wafer.

Preferably, the wafer transfer apparatus further includes a notch engaging portion adapted to come into contact with the peripheral edge of the wafer held on the holding plate under suction in the condition where the notch engaging portion is biased in a radially inward direction of the wafer, the notch engaging portion being engageable with a notch formed on the peripheral edge of the wafer by the rotation of the wafer, in which the operation of the rotational drive portion is controlled so that when the notch engaging portion comes into engagement with the notch, the rotation of the roller portion is stopped to thereby stop the rotation of the wafer.

Preferably, the wafer transfer apparatus further includes a camera unit for imaging the peripheral edge of the wafer in the condition where the wafer is held on the holding plate under suction, in which the operation of the rotational drive portion is controlled according to an orientation of the wafer detected by the camera unit.

Preferably, the rotational drive portion includes a rotating shaft rotatable about its axis and a rotational drive source connected to the rotating shaft for rotating the rotating shaft, the rotating shaft being connected to the roller portion in the rotational drive portion, whereby when the rotational drive source is operated, the rotating shaft is rotated about its axis to thereby rotate the roller portion.

Preferably, the wafer transfer apparatus further includes an external rotational drive portion for rotating the roller portion in the rotational drive portion in the condition where the external rotational drive portion is in contact with the outer circumferential surface of the roller portion in the rotational drive portion.

The holding plate of the wafer transfer apparatus according to one aspect of the present invention is provided with the suction holding portion for holding the wafer under suction in a noncontact fashion. The wafer transfer apparatus further includes the three or more restricting members. Each restricting member has a roller portion rotatable about its axis. The roller portion of each restricting member is adapted to come into contact with the peripheral edge of the wafer held under suction by the suction holding portion, thereby restricting the movement of the wafer with respect to the holding plate in a direction parallel to one side of the wafer. Accordingly, the wafer can be set at a predetermined position on the holding plate in the condition where the wafer is held under suction by the suction holding portion of the wafer transfer apparatus. Further, at least one of the three or more restricting members functions as a rotational drive portion for rotating the roller portion about its axis to thereby rotate the wafer in the condition where the roller portion is in contact with the peripheral edge of the wafer. Accordingly, the wafer can be rotated by using the rotational drive portion to adjust the orientation of the wafer to a predetermined orientation in the condition where the wafer is held under suction by the suction holding portion of the wafer transfer apparatus. As a result, it is possible to eliminate a positioning apparatus provided separately from the wafer transfer apparatus and also eliminate a positioning (centering) step using this positioning apparatus.

The above and other objects, features, and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a wafer transfer apparatus according to a first preferred embodiment of the present invention;

FIG. 2A is a perspective view of a wafer as viewed from the front side thereof;

FIG. 2B is a perspective view of the wafer as viewed from the back side thereof;

FIG. 2C is a perspective view similar to FIG. 2B, depicting another configuration of the wafer;

FIG. 3 is a top plan view of a hand portion included in the wafer transfer apparatus depicted in FIG. 1 in the condition where the wafer is held on a holding plate according to the first preferred embodiment;

FIG. 4 is a partially sectional side view of the hand portion depicted in FIG. 3;

FIG. 5 is a view similar to FIG. 3, depicting a second preferred embodiment of the present invention;

FIG. 6A is a view similar to FIG. 3, depicting a third preferred embodiment of the present invention; and

FIG. 6B is a perspective view of an external rotational drive portion depicted in FIG. 6A.

### DETAILED DESCRIPTION OF THE PREFERRED EMBODIMENTS

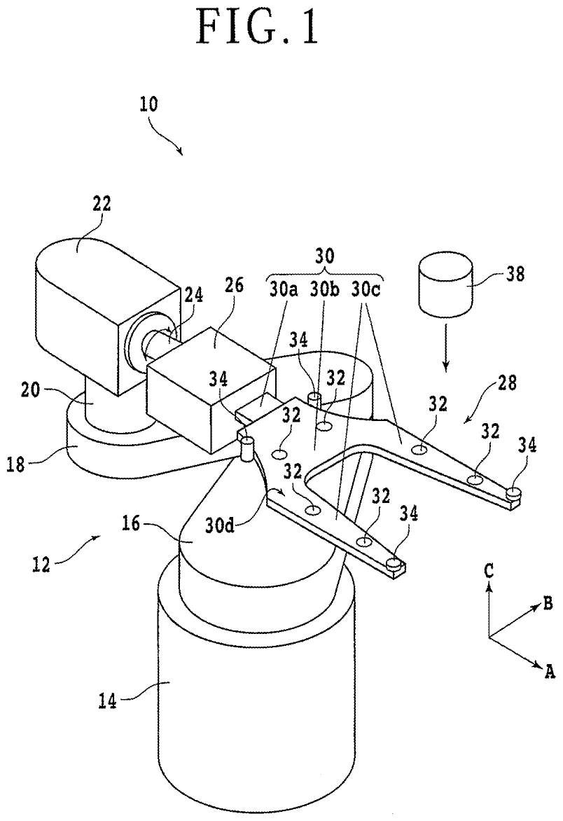

A preferred embodiment of the present invention will now be described with reference to the attached drawings. FIG. 1 is a perspective view of a wafer transfer apparatus 10 according to a first preferred embodiment of the present invention. In FIG. 1, the direction depicted by an arrow A is defined as a first direction, the direction depicted by an arrow B is defined as a second direction perpendicular to the first direction A, and the direction depicted by an arrow C is defined as a third direction perpendicular both to the first direction A and to the second direction B. The third direction C is a vertical direction along the height of the wafer transfer apparatus 10. The wafer transfer apparatus 10 is provided in a processing apparatus (not depicted) such as a cutting apparatus, a grinding apparatus, a polishing apparatus, a grinding and polishing apparatus, and a laser processing apparatus. Further, the wafer transfer apparatus 10 may be provided in a tape mounter (not depicted) for attaching a protective sheet or the like formed of resin to a wafer.

The wafer transfer apparatus 10 is what is called a multi-joint robot. The wafer transfer apparatus 10 includes a moving unit 12 as an articulated link having an open loop structure. The moving unit 12 has a cylindrical first support and rotating portion 14. The first support and rotating portion 14 has a cylindrical housing. A moving mechanism (not depicted) is connected to the bottom of the housing. This moving mechanism is vertically movable in the third direction C (vertical direction). Accordingly, the first support and rotating portion 14 is movable by this moving mechanism in the third direction C.

A first rotating shaft (not depicted) substantially parallel to the third direction C is provided in the housing of the first support and rotating portion 14. A first drive source (not depicted) such as a motor is connected to the bottom of the first rotating shaft. A first link 16 is connected at one end thereof to the top of the first rotating shaft. More specifically, the top of the first rotating shaft is connected to the bottom of the first link 16 at its one end. By operating the first drive source, the first rotating shaft is rotated to thereby rotate the first link 16 about the axis of the first rotating shaft located at one end of the first link 16. That is, the first link 16 is rotated about the axis of the first rotating shaft in a plane parallel to an A-B plane defined by the first direction A and the second direction B.

A first pulley (not depicted) is provided at one end of the first link 16. A second pulley (not depicted) is provided at the other end of the first link 16. The second pulley is connected through a belt (not depicted) to the first pulley. Accordingly, the second pulley is rotatable through the belt by rotating the first pulley. All of the first pulley, the belt, and the second pulley are provided in the housing of the first link 16. A second rotating shaft (not depicted) substantially parallel to the third direction C is connected to the second pulley. Accordingly, the second rotating shaft is rotated by the rotation of the second pulley. A second link 18 is connected at one end thereof to the top of the second rotating shaft. More specifically, the bottom of the second link 18 at its one end is connected to the top of the second rotating shaft. Accordingly, the second link 18 is rotatable about the axis of the second rotating shaft located at one end of the second link 18. That is, when the first pulley is rotated, the second pulley is rotated through the belt, so that the second link 18 is rotated about the axis of the second rotating shaft in a plane parallel to the A-B plane.

A third rotating shaft (not depicted) substantially parallel to the third direction C is connected to the other end of the second link 18. More specifically, the third connecting shaft is connected to the top of the second link 18 at the other end thereof. The third rotating shaft is provided in a cylindrical housing 20. A second drive source (not depicted) such as a motor is connected to the bottom of the third rotating shaft. Accordingly, the third rotating shaft is rotated by operating the second drive source. A third link 22 is connected to the top of the third rotating shaft. More specifically, the bottom of the third link 22 is connected to the top of the third rotating shaft. Accordingly, by operating the second drive source, the third rotating shaft is rotated about its axis, so that the third link 22 is rotated about the axis of the third rotating shaft in a plane parallel to the A-B plane. An arm rotating shaft 24 having a rotation axis parallel to the A-B plane projects from a side surface of the third link 22.

A third drive source (not depicted) such as a motor is provided in the housing of the third link 22. The third drive source is connected to one end of the arm rotating shaft 24. Accordingly, by operating the third drive source, the arm rotating shaft 24 is rotated about its axis parallel to the A-B plane. A box-shaped arm 26 is fixed at one end thereof to the other end of the arm rotating shaft 24. A hand portion 28 as an end effector is connected to the other end of the arm 26. The hand portion 28 has a holding plate 30 formed of metal or ceramic, for example.

The holding plate 30 has a rectangular wrist portion 30a located at one end of the hand portion 28 (i.e., at the end connected to the arm 26). The holding plate 30 further has a connecting portion 30b connected to the wrist portion 30a at its front end opposite to the arm 26. The connecting portion 30b is wider than the wrist portion 30a. The holding plate 30 further has a pair of finger portions 30c (two finger portions 30c) connected to the connecting portion 30b at its front end opposite to the wrist portion 30a. The two finger portions 30c are formed so as to be symmetrical with respect to the lateral center of the connecting portion 30b. Each finger portion 30c extends in the direction substantially parallel to the axis direction of the arm rotating shaft 24 (i.e., in the longitudinal direction of the holding plate 30). The two finger portions 30c are spaced from each other in the lateral direction of the holding plate 30 perpendicular to the longitudinal direction thereof.

The holding plate 30 has a holding surface 30d as the front side. A plurality of pads 32 is exposed to the holding surface 30d of the holding plate 30 so as to be slightly projected therefrom. Each pad 32 functions as a suction holding portion for holding a wafer 11 (which will be hereinafter described in detail) under suction. In the preferred embodiment, the plural pads 32 are six pads 32. Of these six pads 32, two pads 32 are provided on the connecting portion 30b in such a manner as to be spaced from each other in the lateral direction of the holding plate 30. Further, two pads 32 are provided on each finger portion 30c in such a manner as to be spaced from each other in the longitudinal direction of the holding plate 30. However, the plural pads 32 are not limited in number, layout, etc.

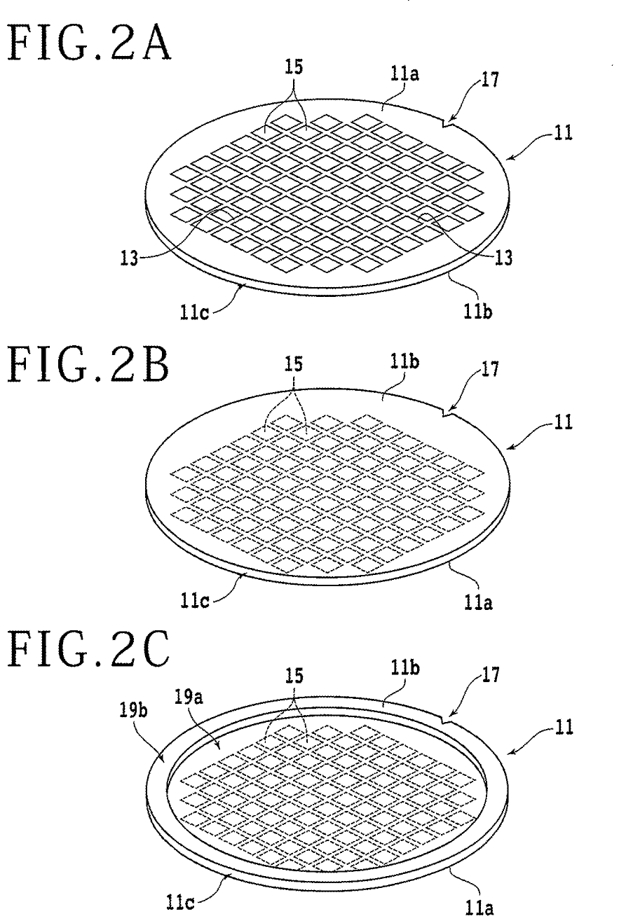

Each pad 32 is a substantially disk-shaped member having an annular recess exposed to the front side. A plurality of nozzles (not depicted) for spraying a fluid such as air is provided on the inner circumferential surface of the annular recess of each pad 32. These plural nozzles are spaced from each other in the circumferential direction of the annular recess of each pad 32. For example, four nozzles are equally spaced in the circumferential direction of the annular recess of each pad 32. In the case that the fluid is air, each nozzle is connected to an air source (not depicted) for supplying air to each nozzle. When the air source is operated to supply air to each nozzle, the air is sprayed from the exposed surface (front side) of each pad 32. When the wafer 11 is placed on the holding plate 30 in such a manner that one side (e.g., back side 11b as depicted in FIGS. 2A to 2C) of the wafer 11 is opposed to each pad 32 in the condition where the air is sprayed from each pad 32, the air is allowed to flow in a gap defined between the one side of the wafer 11 and each pad 32.

When the speed of the flow of air flowing in the gap is increased, the pressure in the gap is decreased in accordance with Bernoulli theorem. As a result, a negative pressure lower than the atmospheric pressure by a predetermined pressure is produced on the exposed surface of each pad 32. Owing to this negative pressure, the wafer 11 is held on the holding surface 30d under suction in a noncontact condition such that the wafer 11 is not in contact with the holding surface 30d and each pad 32. The air to be sprayed from the exposed surface of each pad 32 is sprayed like a cyclone, for example. As a modification, the air may be sprayed radially from the exposed surface of each pad 32. However, the flow of the air to be sprayed is suitably adjusted in direction, amount, etc. so that the wafer 11 is not rotated in a plane parallel to the one side of the wafer 11 opposed to each pad 32.

The wafer 11 to be held on the holding plate 30 will now be described with reference to FIGS. 2A to 2C. FIG. 2A is a perspective view of the wafer 11 as viewed from the front side 11a thereof, and FIG. 2B is a perspective view of the wafer 11 as viewed from the back side 11b thereof. The wafer 11 has a disk-shaped substrate having a diameter of 300 mm, for example. A plurality of crossing division lines (streets) 13 is formed on the front side 11a of the wafer 11 to thereby define a plurality of separate regions where a plurality of devices 15 such as integrated circuits (ICs) is respectively formed.

The substrate of the wafer 11 is formed of silicon (Si) in the preferred embodiment. However, the substrate of the wafer 11 is not limited in material, shape, structure, size, etc. That is, the substrate of the wafer 11 may be formed of any semiconductors other than silicon. Further, the substrate of the wafer 11 may be formed of ceramic or resin, for example. Further, the devices 15 are not limited in kind, number, shape, structure, size, layout, etc. The devices 15 may not be formed on the front side 11a of the wafer 11. The wafer 11 has a peripheral edge 11c, and a bevel portion is formed between the front side 11a and the peripheral edge 11c. Further, another bevel portion is also formed between the back side 11b and the peripheral edge 11c. Further, a notch 17 indicating the crystal orientation in the substrate of the wafer 11 is formed on the peripheral edge 11c of the wafer 11.

The wafer 11 is not limited to the example depicted in FIGS. 2A and 2B. For example, the wafer 11 may be what is called a bumped wafer having a plurality of bumps (not depicted) formed of metal on the front side 11a. FIG. 2C is a perspective view of the wafer 11 as another example as viewed from the back side 11b thereof. As depicted in FIG. 2C, a circular recess 19a may be formed on the back side 11b of the wafer 11 in its central area. The circular recess 19a may be formed by grinding the back side 11b. By forming the circular recess 19a on the back side 11b of the wafer 11 at its central area, a peripheral ring 19b can be left as a reinforcing portion on the back side 11b of the wafer 11 in its peripheral area surrounding the central area. Accordingly, as compared with the case that the circular recess 19a is not formed, warpage in the wafer 11 can be reduced and the strength of the wafer 11 can be increased.

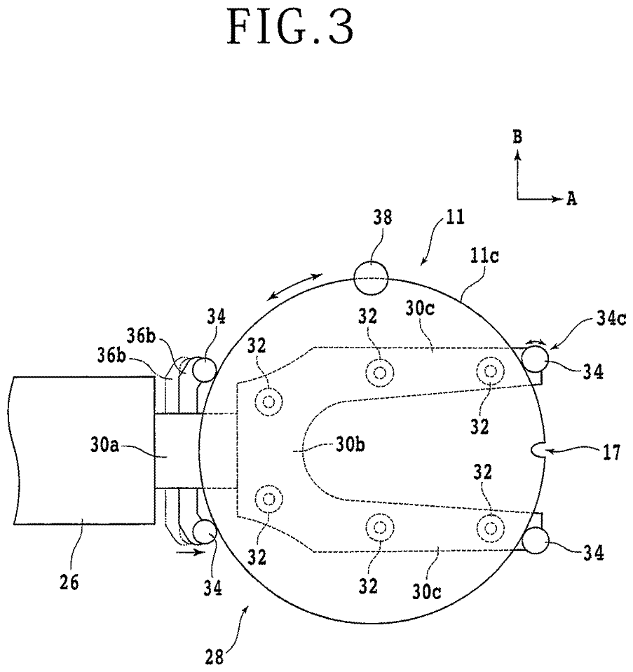

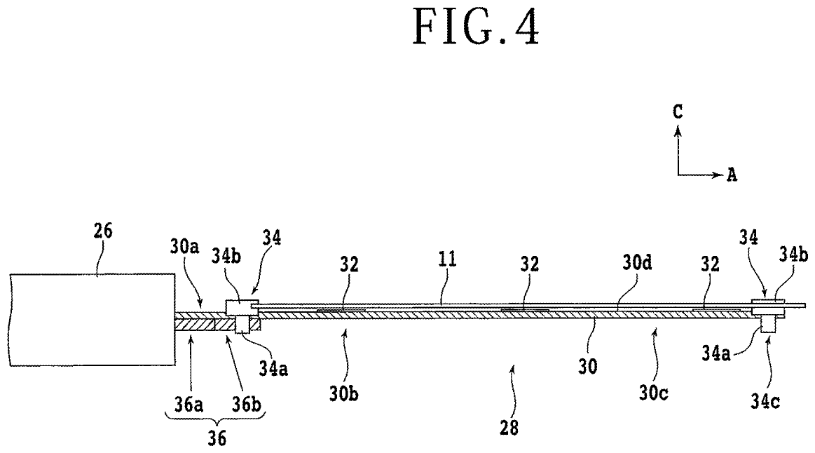

Referring to FIGS. 1, 3, and 4, there are depicted four roller clamps 34 as another component of the wafer transfer apparatus 10. While the four roller clamps 34 are provided in the preferred embodiment, three or more roller clamps 34 are essentially provided in the present invention. FIG. 3 is a top plan view of the hand portion 28 in the condition where the wafer 11 is held on the holding plate 30. FIG. 4 is a partially sectional side view of the hand portion 28 depicted in FIG. 3. As depicted in FIGS. 1, 3, and 4, the hand portion 28 is provided with the three or more roller clamps (restricting members) 34 for restricting the movement of the wafer 11 held under suction by the plural pads 32 in a direction parallel to the one side (e.g., the back side 11b) of the wafer 11 opposed to the holding surface 30d of the holding plate 30. The movement of the wafer 11 in a direction parallel to the one side of the wafer 11 as mentioned above means the movement in a linear direction including the first direction A and the second direction B, and does not mean the rotation of the wafer 11 about a predetermined axis.

Of the four roller clamps 34, one roller clamp 34 is provided at the front end portion of each finger portion 30c. Further, a pair of roller clamps (two roller clamps) 34 are provided at the opposite side positions with respect to the wrist portion 30a. Thus, the totally four roller clamps 34 are provided in the wafer transfer apparatus 10. As depicted in FIGS. 3 and 4, a moving plate 36 is provided below the wrist portion 30a, and the two roller clamps 34 provided at the opposite side positions with respect to the wrist portion 30a are connected to the moving plate 36. The moving plate 36 is not depicted in FIG. 1.

The moving plate 36 is movable back and forth in the longitudinal direction of the holding plate 30 by an actuator (not depicted). As depicted in FIG. 4, the moving plate 36 has a first area 36a connected to the other end (front end) of the arm 26. The moving plate 36 further has a bar-like second area 36b connected to the first area 36a at its front end opposite to the arm 26. The second area 36b has a length larger than the width of the wrist portion 30a. The second area 36b has a symmetrical shape with respect to a predetermined center line coinciding with the lateral center of the wrist portion 30a. The two roller clamps 34 provided at the opposite side positions with respect to the wrist portion 30a are mounted at the opposite ends of the second area 36b.

The structure of each roller clamp 34 will now be described. As depicted in FIG. 4, each roller clamp 34 provided at the front end portion of each finger portion 30c has a cylindrical support portion 34a fixedly mounted. Similarly, each roller clamp 34 provided at each end portion of the second area 36b has a cylindrical support portion 34a fixedly mounted. A disk-shaped roller portion 34b is rotatably supported to each support portion 34a at its upper end. That is, each support portion 34a has a rotating shaft (not depicted) extending in the third direction C and rotatable about the axis thereof, and each roller portion 34b is fixed to the upper end portion of the rotating shaft of the corresponding support portion 34a. The axis (center) of each roller portion 34b coincides with the axis of the rotating shaft of the corresponding support portion 34a. Each roller portion 34b has a diameter larger than that of each support portion 34a. Each roller portion 34b is formed of a resin foam having a hardness to such an extent that the wafer 11 is not damaged by the resin foam. Each roller portion 34b has a coefficient of friction to such an extent that each roller portion 34b does not slip on the peripheral edge 11c of the wafer 11 when coming into rolling contacted therewith.

The roller portion 34b of each roller clamp 34 is rotatable about its axis in the condition where the roller portion 34b is in contact with the peripheral edge 11c of the wafer 11. At least one rotation axis (not depicted) of the three or more roller clamps 34 (e.g., the four roller clamps 34 in the preferred embodiment) is provided with a first rotational drive source 34c such as a motor and an actuator for rotating the corresponding roller portion 34b. More specifically, the first rotational drive source 34c is connected to the bottom of the rotating shaft (not depicted) of this at least one roller clamp 34. This roller clamp 34 including the first rotational drive source 34c functions as a rotational drive portion for rotating the wafer 11 about its center. In the example depicted in FIGS. 3 and 4, the roller clamp 34 provided at the front end of the finger portion 30c on one side in the second direction B includes the first rotational drive source 34c, and this roller clamp 34 functions as the rotational drive portion.

In the preferred embodiment, the first rotational drive source 34c is operated in the condition where the peripheral edge 11c of the wafer 11 is clamped at different four positions by the four roller portions 34b, thereby rotating the rotating shaft and the roller portion 34b of the rotational drive portion. As a result, the wafer 11 can be rotated about its center in the condition where the movement of the wafer 11 is restricted in a direction parallel to one side of the wafer 11. For example, in the case that the roller portion 34b of the rotational drive portion is rotated clockwise as viewed in FIG. 3 by operating the first rotational drive source 34c, the wafer 11 can be rotated counterclockwise about its center as viewed in FIG. 3 and the other roller portions 34b are allowed to rotate clockwise as viewed in FIG. 3. Similarly, in the case that the roller portion 34b of the rotational drive portion is rotated counterclockwise as viewed in FIG. 3 by operating the first rotational drive source 34c, the wafer 11 can be rotated clockwise about its center as viewed in FIG. 3 and the other roller portions 34b are allowed to rotate counterclockwise as viewed in FIG. 3. While the roller clamp 34 functioning as the rotational drive portion is provided at the front end of the finger portion 30c on one side in the second direction B as depicted in FIG. 3 in the preferred embodiment, the roller clamp 34 functioning as the rotational drive portion may be any one of the other roller clamps 34. Further, while the rotational drive portion is configured by the single roller clamp 34 in the preferred embodiment, the rotational drive portion may be configured by two or more roller clamps 34.

As depicted in FIG. 1, the wafer transfer apparatus 10 further includes a camera unit 38 opposed to the holding surface 30d of the holding plate 30. The camera unit 38 includes a complementary metal oxide semiconductor (CMOS) image sensor or a charge coupled device (CCD) image sensor, for example. The camera unit 38 functions to image the peripheral edge 11c of the wafer 11 held on the holding surface 30d and then output an image obtained to a control portion which will be hereinafter described. The camera unit 38 in the preferred embodiment is fixed at a predetermined position separate from the holding plate 30 so as to image the peripheral edge 11c of the wafer 11 from the upper side thereof. However, the camera unit 38 may be fixed to the holding plate 30 at a side position thereof on the precondition that the size of the camera unit 38 is small to such an extend that the camera unit 38 fixed to the holding plate 30 is allowed to enter the cassette storing the plural wafers 11. In this case, the camera unit 38 fixed to the holding plate 30 may be located so as to image the peripheral edge 11c of the wafer 11 from the upper side thereof or from the lower side thereof.

The wafer transfer apparatus 10 is a part of the processing apparatus (not depicted). The operation of the wafer transfer apparatus 10 and the operation of the camera unit 38 are controlled by a control portion (not depicted) for controlling the operation of the processing apparatus. The control portion is configured by a computer including a computing unit such as a central processing unit (CPU) and a storing unit such as a flash memory. By operating the computing unit according to software such as a program stored in the storing unit, the control portion functions as specific means provided by the cooperation of the software and the computing unit (hardware resources). The control portion includes an image processing portion (not depicted) for processing the image obtained by the camera unit 38 to thereby detect the notch 17 of the wafer 11. For example, this image processing portion is realized by software stored in the storing unit in the preferred embodiment. However, this image processing portion is not limited to such software, but may be hardware such as an application specific integrated circuit (ASIC).

There will now be described a method of transferring the wafer 11 by using the wafer transfer apparatus 10 according to the first preferred embodiment. The processing apparatus including the wafer transfer apparatus 10 includes a cassette table (not depicted) for mounting the cassette (not depicted). Although not depicted, the cassette storing the plural wafers 11 is mounted on the cassette table included in the processing apparatus. First, the moving unit 12 is operated to insert the hand portion 28 into the cassette (inserting step S10). Thereafter, a fluid such as air is sprayed from the plural pads 32 to thereby hold the back side 11b of the wafer 11 under suction in a noncontact fashion (suction holding step S20).

Thereafter, the moving plate 36 is moved from a standby position depicted by a phantom line in FIG. 3 where the moving plate 36 is previously set near the arm 26, toward the connecting portion 30b until the peripheral edge 11c of the wafer 11 comes into contact with the roller portion 34b of each roller clamp 34 (contact making step S30). Accordingly, the movement of the wafer 11 in a direction parallel to the back side 11b of the wafer 11 is restricted by the four roller clamps 34. After positioning the wafer 11 in the contact making step S30, the moving unit 12 is operated to draw the hand portion 28 out of the cassette and then position the peripheral edge 11c of the wafer 11 below the camera unit 38. Thereafter, the rotational drive portion is operated to rotate the wafer 11 about its center, and the camera unit 38 is operated to image the peripheral edge 11c of the wafer 11 (imaging step S40).

At this time, the image processing portion processes an image obtained to detect the notch 17 in the image. When the notch 17 is detected in the image, the rotation of the wafer 11 is stopped. Thereafter, the control portion calculates the amount of deviation of the orientation of the wafer 11 (i.e., the position of the notch 17) from a predetermined orientation (i.e., the amount of deviation of the angular position of the notch 17 from a predetermined angular position). As the result of this calculation, the control portion operates the first rotational drive source 34c to rotate the wafer 11 by a necessary angle according to the orientation of the notch 17 (wafer rotating step S50). As described above, the movement of the wafer 11 in a direction parallel to the back side 11b of the wafer 11 is restricted by the four roller clamps 34. However, the movement of the wafer 11 in its circumferential direction, that is, the rotation of the wafer 11 is not restricted.

By rotating the roller portion 34b of the rotational drive portion about the axis of this roller portion 34b, the wafer 11 can be rotated about its center as a predetermined axis to thereby move the notch 17 to a predetermined position with respect to the hand portion 28. That is, the orientation of the wafer 11 can be adjusted. In this manner, the positioning of the wafer 11 and the adjustment of the orientation of the wafer 11 can be performed in the condition where the wafer 11 is held by the hand portion 28. Accordingly, it is possible to eliminate a positioning apparatus provided separately from the wafer transfer apparatus 10 and also eliminate a positioning (centering) step using this positioning apparatus.

After performing the wafer rotating step S50, the moving unit 12 is operated to transfer the wafer 11 held under suction by the hand portion 28 to a chuck table (not depicted) provided in a processing area, this chuck table being included in the processing apparatus (transfer step S60). At this time, the third drive source (not depicted) is operated to rotate the arm rotating shaft 24 by 180 degrees, thereby inverting the wafer 11. Since the wafer 11 is held on the holding surface 30d under suction, there is no possibility that the wafer 11 may drop from the holding surface 30d inverted (i.e., oriented downward). As a result, the wafer 11 is mounted on the chuck table in such a manner that the back side 11b of the wafer 11 is exposed upward and the front side 11a of the wafer 11 is opposed to the upper surface of the chuck table. While the back side 11b of the wafer 11 is held on the holding surface 30d in the preferred embodiment, the front side 11a of the wafer 11 may be held on the holding surface 30d.

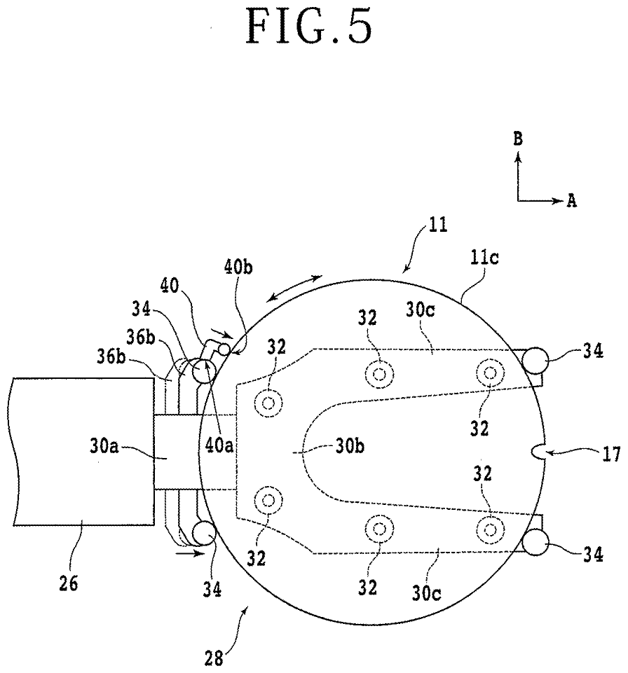

A second preferred embodiment of the wafer transfer apparatus 10 will now be described with reference to FIG. 5. FIG. 5 is a top plan view of the hand portion 28 according to the second preferred embodiment. As depicted in FIG. 5, the hand portion 28 according to the second preferred embodiment includes a notch engaging portion 40 in place of the camera unit 38 used in the first preferred embodiment. The notch engaging portion 40 is a bar-like member having a substantially L-shaped configuration as viewed in plan. The notch engaging portion 40 has one end 40a and the other end 40b. The one end 40a of the notch engaging portion 40 is rotatably connected to one end of the second area 36b of the moving plate 36. Further, biasing means (not depicted) such as a spring is connected to the one end 40a of the notch engaging portion 40, so as to normally bias the notch engaging portion 40 in a clockwise direction as viewed in FIG. 5. The other end 40b of the notch engaging portion 40 has a projection shape adapted to be fitted into a recess shape of the notch 17. The notch engaging portion 40 is arranged so that the other end 40b is oriented to the connecting portion 30b and the finger portions 30c rather than to the arm 26.

There will now be described a method of transferring the wafer 11 by using the wafer transfer apparatus 10 according to the second preferred embodiment. Also in the second preferred embodiment, the inserting step S10 and the suction holding step S20 are similarly performed. The contact making step S30 is next performed to move the moving plate 36 until each roller clamp 34 comes into contact with the peripheral edge 11c of the wafer 11 held on the holding surface 30d under suction. At this time, the other end 40b of the notch engaging portion 40 is also brought into contact with the peripheral edge 11c of the wafer 11 by a biasing force acting in the radially inward direction of the wafer 11, in which this biasing force is produced by the biasing means connected to the one end 40a of the notch engaging portion 40.

In the second preferred embodiment, the imaging step S40 is not performed. Accordingly, after performing the contact making step S30, the wafer rotating step S50 is performed to rotate the wafer 11 by operating the roller clamp 34 as the rotational drive portion, i.e., by operating the first rotational drive source 34c. At this time, the control portion controls the operation of this roller clamp 34 as the rotational drive portion in such a manner that when the other end 40b of the notch engaging portion 40 comes into engagement with the notch 17, the rotation of this roller clamp 34 is stopped to thereby stop the rotation of the wafer 11. Thus, the wafer 11 is suitably rotated to move the notch 17 to a predetermined position with respect to the hand portion 28. Thereafter, the transfer step S60 is similarly performed as in the first preferred embodiment. Also in the second preferred embodiment, the positioning of the wafer 11 and the adjustment of the orientation of the wafer 11 can be performed in the condition where the wafer 11 is held by the hand portion 28. Accordingly, it is possible to eliminate a positioning apparatus provided separately from the wafer transfer apparatus 10 and also eliminate a positioning (centering) step using this positioning apparatus.

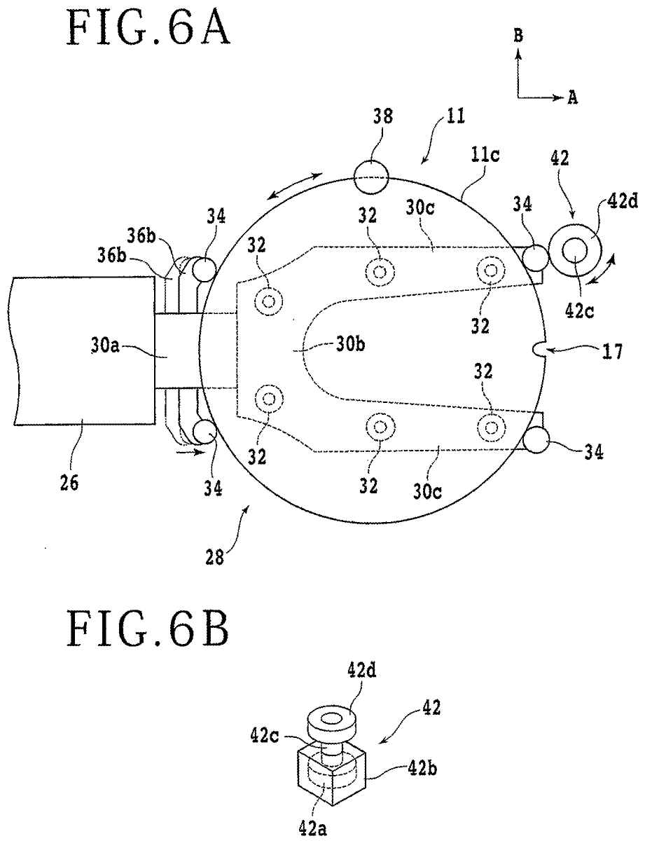

A third preferred embodiment of the wafer transfer apparatus 10 will now be described with reference to FIGS. 6A and 6B. FIG. 6A is a top plan view of the hand portion 28 according to the third preferred embodiment. In the third preferred embodiment, the roller clamp 34 functioning as the rotational drive portion does not include the first rotational drive source 34c. In addition to this rotational drive portion excluding the first rotational drive source 34c, an external rotational drive portion 42 as a part of the wafer transfer apparatus 10 is fixed at a predetermined position separate from the holding plate 30. FIG. 6B is a perspective view of the external rotational drive portion 42. As depicted in FIG. 6B, the external rotational drive portion 42 has a second rotational drive source 42a such as a motor and an actuator. That is, the second rotational drive source 42a is provided in place of the first rotational drive source 34c according to the third preferred embodiment.

As depicted in FIG. 6B, the external rotational drive portion 42 includes a boxlike housing 42b. The second rotational drive source 42a is provided in this housing 42b. A rotating shaft 42c is connected at a lower end thereof to the second rotational drive source 42a. A disk-shaped roller portion 42d is fixed to an upper end of the rotating shaft 42c projecting from the housing 42b. The roller portion 42d has a diameter larger than that of the rotating shaft 42c and is formed of a resin foam, for example, as similar to the roller portion 34b of each roller clamp 34. However, the material of the roller portion 42d is not especially limited on the precondition that the roller portion 42d has a coefficient of friction to such an extent that it does not slip on the roller portion 34b. That is, the outer circumferential surface of the roller portion 42d of the external rotational drive portion 42 is in contact with the outer circumferential surface of the roller portion 34b of one of the four roller clamps 34 so that the rotation of the roller portion 42d can be transmitted to the roller portion 34b of the roller clamp 34 functioning as the rotational drive portion for rotating the wafer 11. Accordingly, when the second rotational drive source 42a of the external rotational drive portion 42 is operated, the roller portion 42d is rotated about its axis to thereby rotate the roller portion 34b about its axis, so that the wafer 11 can be rotated about its center by the rotation of the roller clamp 34 as the rotational drive portion.

As mentioned above, the method of transferring the wafer 11 according to the third preferred embodiment is different from the method according to the first preferred embodiment in the point that the drive source for rotating the wafer 11 in the wafer rotating step S50 is provided by the second rotational drive source 42a rather than the first rotational drive source 34c. In the other points, the third preferred embodiment is the same as the first preferred embodiment. In the third preferred embodiment, the first rotational drive source 34c is eliminated from the hand portion 28, so that the structure of the hand portion 28 can be simplified as compared with the first preferred embodiment. Also in the third preferred embodiment, the positioning of the wafer 11 and the adjustment of the orientation of the wafer 11 can be performed in the condition where the wafer 11 is held by the hand portion 28. Accordingly, it is possible to eliminate a positioning apparatus provided separately from the wafer transfer apparatus 10 and also eliminate a positioning (centering) step using this positioning apparatus. In this preferred embodiment, the external rotational drive portion 42 is provided separately from the holding plate 30. As a modification, the external rotational drive portion 42 may be fixed to the holding plate 30 at a side position with respect thereto on the precondition that the size of the external rotational drive portion 42 is small to such an extent that it is allowed to enter the cassette.

In addition, the structure, method, etc. according to each preferred embodiment mentioned above may be suitably modified without departing from the scope of the object of the present invention. For example, the structure of the plural pads 32, the flow rate of air to be supplied to the plural pads 32, and the path of air to be supplied to the plural pads 32 may be modified so that the direction of flow of the air to be sprayed from the plural pads 32 becomes different. More specifically, in the case that the holding surface 30d of the hand portion 28 is viewed in top plan, a cyclone-like air flow rotating clockwise may be sprayed from at least one pad 32 provided on one of the two finger portions 30c, and a cyclone-like air flow rotating counterclockwise may be sprayed from at least one pad 32 provided on the other finger portion 30c.

In this case, by adjusting the flow rate of the air to be sprayed from each pad 32, the rotation of the wafer 11 by the rotational drive portion can be assisted by this air flow. For example, in the case that the flow rate of air rotating clockwise is set larger than the flow rate of air rotating counterclockwise, the clockwise rotation of the wafer 11 can be assisted by the air rotating clockwise at the relatively large flow rate in the condition where the wafer 11 is held on the holding surface 30d under suction in a noncontact fashion. Conversely, in the case that the flow rate of air rotating counterclockwise is set larger than the flow rate of air rotating clockwise, the counterclockwise rotation of the wafer 11 can be assisted by the air rotating counterclockwise at the relatively large flow rate in the condition where the wafer 11 is held on the holding surface 30d under suction in a noncontact fashion.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer transfer apparatus comprising:
a holding plate having a holding surface adapted to be opposed to one side of a wafer;
a suction holding portion provided so as to be exposed to said holding surface for holding said wafer under suction in a noncontact fashion in the condition where the one side of said wafer is opposed to said holding surface;
three or more restricting members for restricting the movement of said wafer with respect to said holding plate in a direction parallel to the one side of said wafer, each restricting member having a roller portion rotatable about its axis, said roller portion being adapted to come into contact with the peripheral edge of said wafer held under suction by said suction holding portion, thereby restricting the movement of said wafer;
a moving unit connected to said holding plate for moving said holding plate to thereby transfer said wafer, wherein; and
an external rotational drive portion for rotating said roller portion of one of said three or more restricting members about its axis to thereby rotate said wafer in the condition where said roller portion is in contact with the peripheral edge of said wafer.

2. The wafer transfer apparatus according to claim 1, wherein said external rotational drive portion as a part of said wafer transfer apparatus is fixed at a predetermined position separate from said holding plate.

3. The wafer transfer apparatus according to claim 2, wherein said external rotational drive portion is fixed at a predetermined position of a processing apparatus.

4. The wafer transfer apparatus according to claim 1, wherein said external rotational drive portion has a rotational drive source, and said rotational drive source includes a motor or an actuator.

5. The wafer transfer apparatus according to claim 4, wherein said external rotational drive portion has a rotating shaft and a second roller portion fixed to an end of said rotating shaft, and
said second roller portion has a coefficient of friction to such an extent that said second roller portion does not slip on said roller portion.

6. The wafer transfer apparatus according to claim 5, wherein said second roller portion is formed of a resin foam.

7. The wafer transfer apparatus according to claim 1, further comprising:
a camera unit for imaging the peripheral edge of said wafer in the condition where said wafer is held on said holding plate under suction, wherein
the operation of said external rotational drive portion is controlled according to an orientation of said wafer detected by said camera unit.

8. The wafer transfer apparatus according to claim 7, wherein said camera unit images the peripheral edge of said wafer from the upper side thereof.

9. The wafer transfer apparatus according to claim 7, wherein said camera unit is fixed at a predetermined position separate from said holding plate.

10. The wafer transfer apparatus according to claim 7, wherein said camera unit is fixed to said holding plate at a side position thereof.
